(19) United States
(12) Patent Application Publication
(10) Pub. No.: US 2005/0140405 A1
(43) Pub. Date: Jun. 30, 2005

(54) Power-up circuit semiconductor memory device

(76) Inventors: Chang-Ho Do, Ichon-shi (KR); Jae-Jin Lee, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/788,683

(22) Filed: Feb. 27, 2004

(30) Foreign Application Priority Data
Dec. 30, 2003 (KR) 2003-99600

(51) Int. Cl. H03L 7/00

(52) U.S. Cl. 327/143

(57) ABSTRACT

A power-up circuit includes a power supply voltage level follower unit for outputting a first bias voltage and a second bias voltage which increase or decrease in proportion to a power supply voltage; a first power supply voltage detecting unit for detecting that the power supply voltage becomes a first critical voltage level of the power supply voltage corresponding to a threshold voltage of an NMOS transistor in response to the first bias voltage; a second power supply voltage detecting unit for detecting that the power supply voltage becomes a second critical voltage level of the power supply voltage corresponding to a threshold voltage of a PMOS transistor in response to the second bias voltage; and a summation unit for performing a logic operation to a first detect signal outputted from the first power supply voltage detecting unit and a second detect signal outputted from the second power supply voltage detecting unit to thereby output a confirmation signal, wherein the confirmation signal is activated when the power supply voltage satisfies both of the first and second critical voltage levels.

### FIELD OF INVENTION

The present invention relates to a semiconductor device; and, more particularly, to a power-up circuit for use in a semiconductor memory device.

### DESCRIPTION OF PRIOR ART

In a semiconductor memory device, there are provided with various internal logics and an internal voltage generating block for a stable operation of elements included in the semiconductor memory device. The internal logics should be initialized as a predetermined status before the semiconductor memory device is operated normally.

The internal voltage generating block provides a bias voltage to the internal logics. If the internal voltage does not reach to a proper voltage level after supplying a power supply voltage VDD, there occurs a problem such as a latch-up phenomenon causing reliability of a semiconductor memory device to be degraded. Therefore, a semiconductor memory device is provided with a power-up circuit for initializing the internal logics and preventing the latch-up phenomenon due to an unstable internal power.

When the semiconductor memory device starts to be supplied with a power supply voltage VDD at its initial state, the power-up circuit controls the internal logics, so that the internal logics can be operated after a voltage level of the power supply voltage VDD is higher than a critical voltage level of the power supply voltage VDD.

A power-up signal outputted from the power-up circuit detects a rising of the voltage level of the power supply voltage VDD, whereby the power-up signal is changed from a logic LOW level to a logic HIGH level when the voltage level of the power supply voltage VDD is higher than the critical voltage level.

On the other hand, if the voltage level of the power supply voltage VDD is lowered than the critical voltage level, the power-up signal becomes a logic LOW level.

Generally, when the power-up signal is in a logic LOW level after the power supply voltage VDD is supplied to the semiconductor memory device, latches included in the internal logics are initialized as a predetermined status and the internal voltage generating block is also initialized.

Meanwhile, the critical voltage level is a required voltage level for the internal logics to be operated normally. The critical voltage level is generally set to be higher than a threshold voltage of a metal oxide semiconductor (MOS) transistor for analog circuits to be initialized stably.

FIG. 1 is a schematic circuit diagram showing a conventional power-up circuit included in a semiconductor memory device.

As shown, the conventional power-up circuit includes a power supply voltage level follower unit 100, a power supply voltage trigger unit 110 and a buffering unit 120.

The power supply voltage level follower unit 100 generates a bias voltage Va which increases or decreases linearly in proportion to a power supply voltage VDD. The power supply voltage trigger unit 110 serves to detect that a voltage level of the power supply voltage VDD becomes its critical voltage level in response to the bias voltage Va. The buffering unit 120 buffers a detect bar signal detb outputted from the power supply voltage trigger unit 110 for generating a power-up signal pwrup.

Herein, the voltage level follower unit 100 is provided with a first resistor R1 and a second resistor R2 connected between the power supply voltage VDD and a ground voltage VSS for a voltage division.

The power supply voltage trigger unit 110 includes a P-channel metal oxide semiconductor (PMOS) transistor MP0, an N-channel metal oxide semiconductor (NMOS) transistor MN0 and a first inverter INV0.

The PMOS transistor MP0 is connected between the power supply voltage VDD and a node N1 and its gate is connected to the ground voltage VSS. The NMOS transistor MN0 is connected between the ground voltage VSS and the node N1 and its gate is connected to the bias voltage Va. The first inverter INV0 receives a detect signal det from the node N1 to output the detect bar signal detb. Herein, the PMOS transistor MP0 can be replaced with another load element having the same valid resistance as that of the PMOS transistor MP0.

Meanwhile, the buffering unit 120 is provided with a plurality of inverters INV1 to INV4 for receiving the detect bar signal debt to output the power-up signal pwrup.

FIG. 2 is a timing diagram showing an operation of the conventional power-up circuit shown in FIG. 1.

The bias voltage Va outputted from the power supply voltage level follower unit 100 follows a mathematical formula shown below.

$$Va = \frac{R2}{R1 + R2} \times VDD \qquad FORMULA . 1$$

That is, the bias voltage Va is increased as the voltage level of the power supply voltage VDD is increased. If the bias voltage Va is increased to be higher than a threshold voltage of the NMOS transistor MN0, the NMOS transistor MN0 is turned on and the detect signal det is changed depending on currents flown on the PMOS transistor MP0 and the NMOS transistor MN0.

At an initial state, the detect signal det is increased following the power supply voltage VDD. Thereafter, as the bias voltage Va is increased, the NMOS transistor MN0 has an increased current flow and the detect signal det is changed to a logic LOW level at a predetermined voltage level of the power supply voltage VDD. At this time, when the level of the detect signal det crosses a logic threshold value of the first inverter INV0, a level of the detect bar signal detb is increased following the power supply voltage VDD. The detect bar signal detb outputted from the first inverter INV0 is buffered in the buffering unit 120 and is outputted as the power-up signal pwrup having a logic HIGH level.

However, the conventional power-up circuit determines the critical voltage level of the power supply voltage VDD depending on a threshold voltage of a MOS transistor. Therefore, if the MOS transistor is not stable due to some variations in manufacturing processes, its threshold voltage can be lowered causing abnormal early reset of the power-up signal pwrup. As a result, the abnormal early reset may cause an unstable operation of a semiconductor memory device.

### SUMMARY OF INVENTION

It is, therefore, an object of the present invention to provide a power-up circuit for use in a semiconductor memory device having an ability of preventing an abnormal early reset of a power-up signal.

In accordance with an aspect of the present invention, there is provided a power-up circuit including a power supply voltage level follower unit for outputting a first bias voltage and a second bias voltage which increase or decrease in proportion to a power supply voltage; a first power supply voltage detecting unit for detecting that the power supply voltage becomes a first critical voltage level of the power supply voltage corresponding to a threshold voltage of an NMOS transistor in response to the first bias voltage; a second power supply voltage detecting unit for detecting that the power supply voltage becomes a second critical voltage level of the power supply voltage corresponding to a threshold voltage of a PMOS transistor in response to the second bias voltage; and a summation unit for performing a logic operation to a first detect signal outputted from the first power supply voltage detecting unit and a second detect signal outputted from the second power supply voltage detecting unit to thereby output a confirmation signal, wherein the confirmation signal is activated when the power supply voltage satisfies both of the first and second critical voltage levels.

### BRIEF DESCRIPTION OF THE DRAWINGS

The above and other objects and features of the present invention will become apparent from the following description of preferred embodiments taken in conjunction with the accompanying drawings, in which:

FIG. 1 is a schematic circuit diagram showing a conventional power-up circuit;

FIG. 2 is a timing diagram showing an operation of the conventional power-up circuit shown in FIG. 1;

FIG. 3 is a schematic circuit diagram showing a power-up circuit in accordance with a first preferred embodiment of the present invention; and

FIG. 4 is a schematic circuit diagram showing a power-up circuit in accordance with a second preferred embodiment of the present invention.

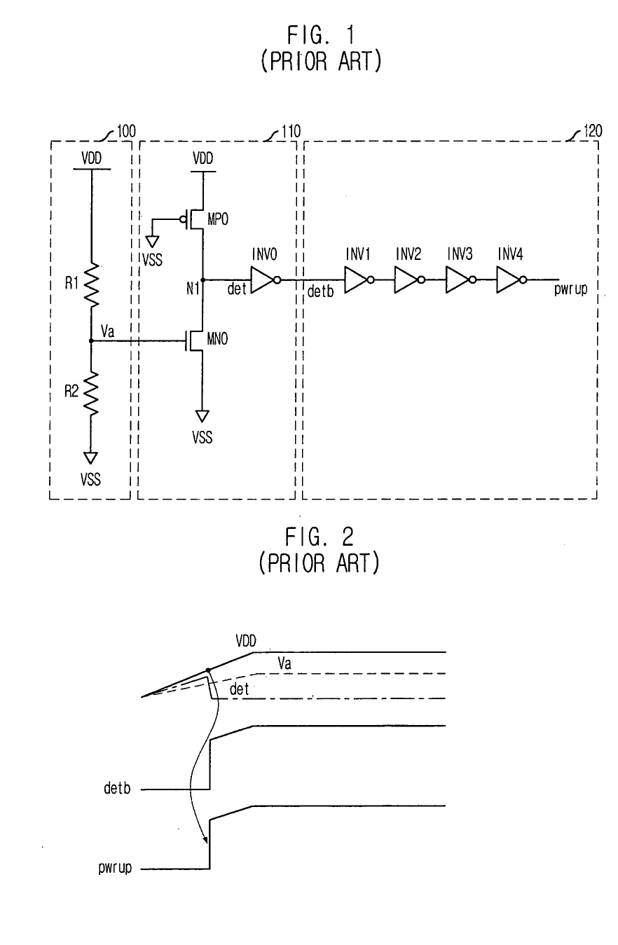

### DETAILED DESCRIPTION OF INVENTION

Hereinafter, a power-up circuit in accordance with the present invention will be described in detail referring to the accompanying drawings.

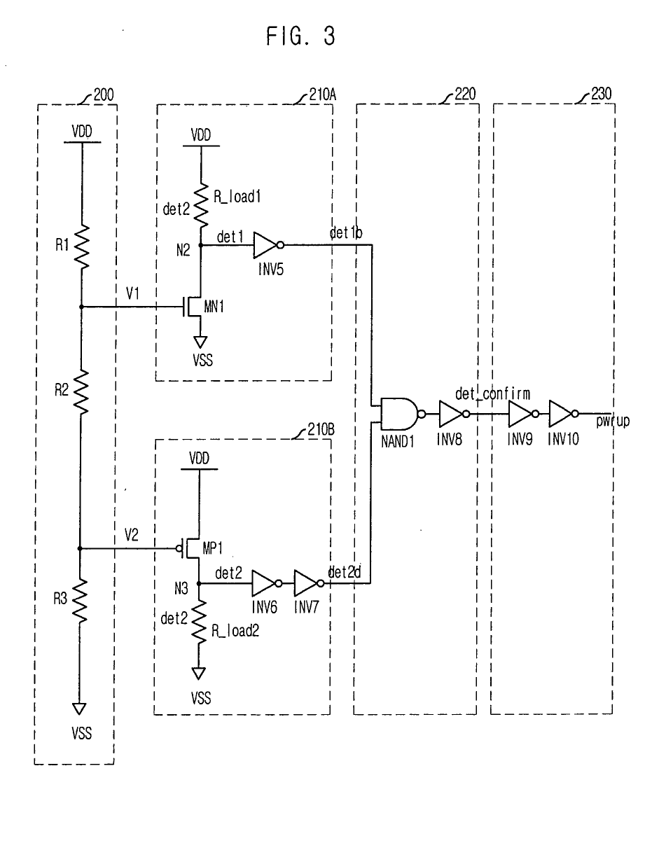

FIG. 3 is a schematic circuit diagram showing a power-up circuit in accordance with a first preferred embodiment of the present invention.

As shown, the power-up circuit includes a power supply voltage level follower unit 200, a first power supply voltage detecting unit 210A, a second power supply voltage detecting unit 210B, a summation unit 220 and a buffering unit 230.

The power supply voltage level follower unit 200 generates a first bias voltage V1 and a second bias voltage V2 which increase or decrease linearly in proportion to a voltage level of a power supply voltage VDD.

The first power supply voltage detecting unit 210A serves to detect that a voltage level of the power supply voltage VDD becomes its first critical voltage level corresponding to a threshold voltage of an N-channel metal oxide semiconductor (NMOS) transistor MN1 in response to the first bias voltage V1, and thus to output a first detect bar signal det1b.

The second power supply voltage detecting unit 210B serves to detect that a voltage level of the power supply voltage VDD becomes its second critical voltage level corresponding to a threshold voltage of a P-channel metal oxide semiconductor (PMOS) transistor MP1 in response to the second bias voltage V2, and thus to output a delayed second detect signal det2d.

The summation unit 220 outputs a confirmation signal det_confirm by performing a logic operation on the first detect bar signal det1b and the delayed second detect signal det2d. Herein, the confirmation signal det_confirm is activated when the power supply voltage VDD satisfies both of the first critical voltage level and the second critical voltage level.

The buffering unit 230 outputs a power-up signal pwrup by buffering the confirmation signal det_confirm.

The power supply voltage level follower unit 200 is provided with a first resistor R1, a second resistor R2 and a third resistor R3 connected between the power supply voltage VDD and a ground voltage VSS for a voltage division. Herein, the first to third resistors R1 to R3 can be replaced with other active elements such as MOS transistors.

The first power supply voltage detecting unit 210A is provided with a first load resistor R_load1, a first inverter INV5 and the NMOS transistor MN1.

The first load resistor R_load1 is connected between the power supply voltage VDD and a first node N2. The NMOS transistor MN1 is connected between the first node N2 and the ground voltage VSS and receives the first bias voltage V1 through a gate of the NMOS transistor MN1. The first inverter INV5 receives a first detect signal det1 from the first node N2. Herein, the first load resistor R_load1 can be replaced with another load element such as a PMOS transistor.

The second power supply voltage detecting unit 210A is provided with a second load resistor R_load2, a second inverter INV6, a third inverter INV7 and the PMOS transistor MP1.

The second load resistor R_load2 is connected between the ground voltage VSS and a second node N3. The PMOS transistor MP1 is connected between the second node N3 and the power supply voltage VDD and receives a second detect signal det2 through a gate of the PMOS transistor MP1. The second inverter INV6 receives the second detect signal det2, and the third inverter INV7 receives an output signal from the second inverter INV6. Herein, the second load resistor R_load2 can be replaced with another load element such as an NMOS transistor.

The summation unit 220 includes a NAND gate NAND1 and a fourth inverter INV8.

The NAND gate NAND1 receives the first detect bar signal det1b and the delayed second detect signal det2d and performs a logic NAND operation to the received two signals. The fourth inverter INV8 receives an output signal from the NAND gate NAND1.

Herein, the NAND gate NAND1 is adopted for the summation unit 220 under an assumption that the first detect bar signal det1b and the delayed second detect signal det2d are activated as a logic HIGH level and the confirmation signal det_confirm is also activated as a logic HIGH level. If all of the first detect bar signal det1b, the delayed second detect signal det2d and the confirmation signal det_confirm are not activated as a logic HIGH level, the summation unit 220 should be embodied as another logic gate. For instance, if the first detect bar signal det1b and the delayed second detect signal det2d are activated as a logic LOW level and the confirmation signal det_confirm is activated as a logic HIGH level, the summation unit 220 can be embodied as a single NOR gate.

The buffering unit 230 includes a fifth inverter INV9 and a sixth inverter INV10 for receiving the confirmation signal det_confirm.

An operation of the power-up circuit is described below.

The first and second bias voltages V1 and V2 follow two mathematical formulas shown below, respectively.

$$\begin{matrix}V1 = \frac{R2 + R3}{R1 + R2 + R3} \times VDD & FORMULA . 2 \\ V2 = \frac{R3}{R1 + R2 + R3} \times VDD & FORMULA . 3\end{matrix}$$

That is, as the power supply voltage VDD increases after it starts to be supplied to the power-up circuit, the first bias voltage V1 is increased in proportion to the power supply voltage VDD. The first detect signal det1 is also increased in proportion to the power supply voltage VDD since the first NMOS transistor MN1 is turned-off. Thereafter, if the first bias voltage V1 becomes higher than a threshold voltage of the NMOS transistor MN1, the NMOS transistor MN1 is turned-on. Thereafter, a signal level of the first detect signal det1 is changed into a logic LOW level. Therefore, the first detect bar signal det1b is outputted as a logic HIGH level from the first inverter INV5 and is increased in proportion to the power supply voltage VDD.

Likewise, if the second bias voltage V2 becomes higher than a threshold voltage of the NMOS transistor MN2, the NMOS transistor MN2 is turned-on. Thereafter, a signal level of the second detect signal det2 is changed into a logic HIGH level. Thereafter, the delayed second detect signal det2d is outputted as a logic HIGH level from the third inverter INV7 and is increased in proportion to the power supply voltage VDD.

Meanwhile, since a threshold voltage characteristic of the NMOS transistor MN1 is different from that of the PMOS transistor MP1, the first detect bar signal det1b and the delayed second detect signal det2d become in a logic HIGH level at different points of time.

In case that both of the first detect bar signal det1b and the delayed second detect signal det2d are in the same logic LOW level or in opposite logic levels, i.e., a logic HIGH level and a logic LOW level, the confirmation signal det_confirm is in a logic LOW level. The confirmation signal det_confirm becomes in a logic HIGH level if both of the first detect bar signal det1b and the delayed second detect signal det2d become in a logic HIGH level. Thereafter, the confirmation signal det_confirm is buffered in the buffering unit 230 and outputted as the power-up signal pwrup in a logic HIGH level.

Therefore, in accordance with the first preferred embodiment, at an initial operation of a semiconductor memory device, the power-up signal pwrup changes its logic level if the power supply voltage VDD is increased to one of the first critical voltage level and the second critical voltage level, wherein the selected critical voltage level is higher than the other. Therefore, if the power-up circuit is applied to the semiconductor memory device, an abnormal early reset of the power-up signal pwrup is prevented. The abnormal early reset of the power-up signal is caused by various factors such as a manufacturing process.

As a result, it is also possible to prevent an abnormal operation of the semiconductor memory device.

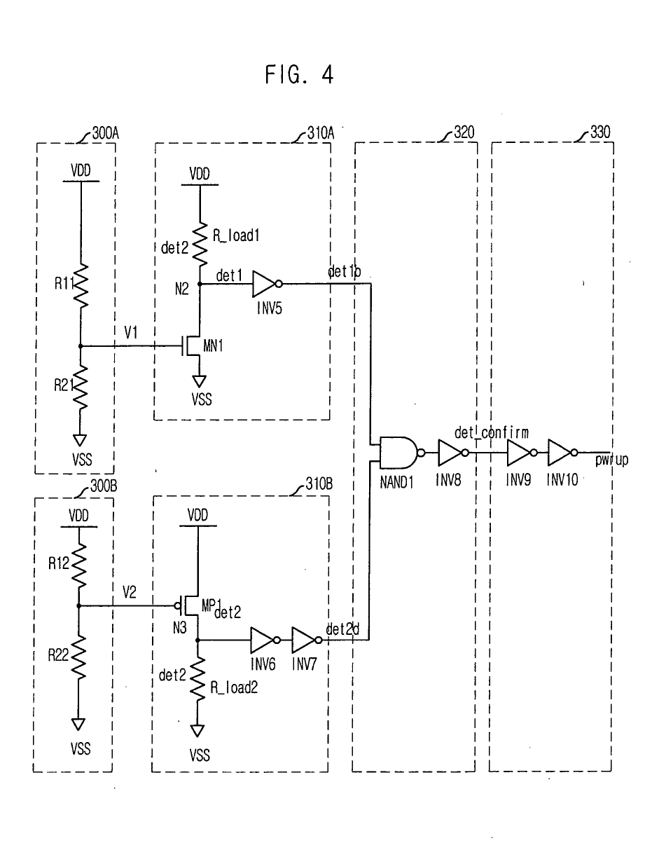

FIG. 4 is a schematic circuit diagram showing a power-up circuit in accordance with a second preferred embodiment of the present invention.

As shown, the power-up circuit in accordance with the second preferred embodiment includes a first power supply voltage level follower unit 300A, a second power supply voltage level follower unit 300B, a first power supply voltage detecting unit 310A, a second power supply voltage detecting unit 310B, a summation unit 320 and a buffering unit 330.

The first power supply voltage level follower unit 300A serves to output a first bias voltage V1 which increases or decreases linearly in proportion to a power supply voltage VDD. The second power supply voltage level follower unit 300B serves to output a second bias voltage V2 which increases or decreases linearly in proportion to the power supply voltage VDD.

The first power supply voltage detecting unit 310A serves to detect that a voltage level of the power supply voltage VDD becomes its first critical voltage level corresponding to a threshold voltage of an NMOS transistor MN1 in response to the first bias voltage V1, and thus to output a first detect bar signal det1b.

The second power supply voltage detecting unit 310B serves to detect that a voltage level of the power supply voltage VDD becomes its second critical voltage level corresponding to a threshold voltage of a PMOS transistor MP1 in response to the second bias voltage V2, and thus to output a delayed second detect signal det2d.

The summation unit 320 outputs a confirmation signal det_confirm by performing a logic operation to the first detect bar signal det1b and the delayed second detect signal det2d. Herein, the confirmation signal det_confirm is activated when the power supply voltage VDD satisfies both of the first critical voltage level and the second critical voltage level.

The buffering unit 330 outputs a power-up signal pwrup by buffering the confirmation signal det_confirm.

That is, the power-up circuit in accordance with the second preferred embodiment includes the first and second power supply voltage level follower units 300A and 300B for outputting the first and second bias voltage V1 and V2, respectively. Therefore, the power-up circuit in accordance with the second preferred embodiment is the same as the power-up circuit in accordance with the first preferred embodiment except for the two power supply voltage level follower units 300A and 300B.

Meanwhile, the first power supply voltage level follower unit 300A includes a first resistor R11 and a second resistor R21 connected between the power supply voltage VDD and the ground voltage VSS for a voltage division. The second power supply voltage level follower unit 300B includes a third resistor R12 and a fourth resistor R22 connected between the power supply voltage VDD and the ground voltage VSS for a voltage division.

Herein, resistance of

$$\frac{R21}{R11 + R21}$$

is equal to the resistance of

$$\frac{R2 + R3}{R1 + R2 + R3}$$

in the FORMULA. 2, and resistance of

$$\frac{R22}{R12 + R22}$$

is equal to the resistance of

$$\frac{R3}{R1 + R2 + R3}$$

in the FORMULA. 3.

An operation of the power-up circuit in accordance with the second preferred embodiment of the present invention is the same as that of the power-up circuit in accordance with the first preferred embodiment of the present invention described above.

Hence, the power-up circuit in accordance with the present invention described above can prevent an abnormal early reset of the power-up signal pwrup. Therefore, a stable operation of a semiconductor memory device can be attained. Particularly, even a semiconductor memory device consuming a low operational voltage can be operated stably through using the above-described power-up circuit.

While the present invention has been described with respect to the particular embodiments, it will be apparent to those skilled in the art that various changes and modifications may be made without departing from the spirit and scope of the invention as defined in the following claims.

1. A power-up circuit for use in a semiconductor memory device, comprising:
a power supply voltage level follower unit for outputting a first bias voltage and a second bias voltage which increase or decrease in proportion to a power supply voltage;
a first power supply voltage detecting unit for detecting that the power supply voltage becomes a first critical voltage level of the power supply voltage corresponding to a threshold voltage of an NMOS transistor in response to the first bias voltage;
a second power supply voltage detecting unit for detecting that the power supply voltage becomes a second critical voltage level of the power supply voltage corresponding to a threshold voltage of a PMOS transistor in response to the second bias voltage; and
a summation unit for performing a logic operation to a first detect signal outputted from the first power supply voltage detecting unit and a second detect signal outputted from the second power supply voltage detecting unit to thereby output a confirmation signal, wherein the confirmation signal is activated when the power supply voltage satisfies both of the first and second critical voltage levels.

2. The power-up circuit as recited in claim 1, further includes a buffering unit for buffering the confirmation signal outputted from the summation unit to thereby output a power-up signal.

3. The power-up circuit as recited in claim 1, wherein the power supply voltage level follower unit includes a first load element, a second load element and a third load element, all connected between the power supply voltage and a ground voltage in series, for outputting the first bias voltage to a first common node between the first load element and the second load element and outputting the second bias voltage to a second common node between the second load element and the third load element.

4. The power-up circuit as recited in claim 1, wherein the power supply voltage level follower unit includes:
a first power supply voltage level follower unit having a first load element and a second load element connected in series between the power supply voltage and a ground voltage; and
a second power supply voltage level follower unit having a third load element and a fourth load element connected in series between the power supply voltage and the ground voltage.

5. The power-up circuit as recited in claim 1, wherein the first power supply voltage detecting unit includes:
a first load element connected between the power supply voltage and a first node;
an NMOS transistor connected between the first node and a ground voltage for receiving the first bias voltage through a gate of the NMOS transistor; and
a first inverter connected to the first node.

6. The power-up circuit as recited in claim 5, wherein the first load element is embodied as a P-channel metal oxide semiconductor (PMOS) transistor connected between the power supply voltage and the first node and receives the ground voltage through a gate of the PMOS transistor.

7. The power-up circuit as recited in claim 5, wherein the second power supply voltage detecting unit includes:
a second load element connected between the ground voltage and a second node;
a PMOS transistor connected between the second node and the power supply voltage for receiving the second bias voltage through a gate of the PMOS transistor;
a second inverter connected to the second node; and
a third inverter for receiving an outputted signal from the second inverter.

8. The power-up circuit as recited in claim 7, wherein the second load element is embodied as an NMOS transistor connected between the ground voltage and the second node and receives the power supply voltage through a gate of the NMOS transistor.

9. The power-up circuit as recited in claim 7, wherein the summation unit includes:
a NAND gate for receiving the first detect signal and the second detect signal; and
a fourth inverter for receiving an outputted signal from the NAND gate.

10. The power-up circuit as recited in claim 1, wherein the summation unit includes a NOR gate for receiving the first detect signal and the second detect signal.

11. The power-up circuit as recited in claim 2, wherein the buffering unit includes buffers connected in serial for receiving the confirmation signal.
